(19) United States
(12) Patent Application Publication
(10) Pub. No.: US 2007/0013294 A1
(43) Pub. Date: Jan. 18, 2007

(54) White light-emitting electroluminescent device

(76) Inventors: Kwan-Yue Jen, Kenmore, WA (US); Petra Inbar, San Diego, CA (US); Joo Hyun Kim, Seoul (KR); Chingfong Shu, Hsin-Chu (TW)

Correspondence Address: CHRISTENSEN, O'CONNOR, JOHNSON, KINDNESS, PLLC, 1420 FIFTH AVENUE, SUITE 2800, SEATTLE, WA, 98101-2347, US

(21) Appl. No.: 11/191,256

(22) Filed: Jul. 27, 2005

Related U.S. Application Data
(60) Provisional application No. 60/591,408, filed on Jul. 27, 2004.

(51) Int. Cl. H01L 51/00

(52) U.S. Cl. 313/504

(57) ABSTRACT

A white light-emitting electroluminescent device having an emissive layer that includes a green light-emitting compound and a red light-emitting compound dispersed in a blue light-emitting host.

### CROSS-REFERENCE TO RELATED APPLICATION

This application claims the benefit of U.S. Provisional Application No. 60/591,408, filed Jul. 27, 2004.

### STATEMENT OF GOVERNMENT LICENSE RIGHTS

This invention was made with government support under Contract No. F49620-01-1-0364, awarded by the Air Force Office of Scientific Research. The government has certain rights in the invention.

### FIELD OF THE INVENTION

The present invention relates to a white light-emitting electroluminescent device having an emissive layer that includes a green light-emitting compound and a red light-emitting compound dispersed in a blue light-emitting host.

### BACKGROUND OF THE INVENTION

Organic light-emitting diodes (OLEDs) are very attractive for flat panel displays due to their high quantum efficiency, light weight, and cost effectiveness. A tremendous effort has been spent on improving the efficiency, emitting color, and lifetime of these OLEDs through the development of better materials and more efficient device structures.

Recently, white organic light-emitting devices (WOLEDs) have been considered for applications in lighting and backplane light for liquid crystal displays. The ideal Commission Internationale d'Enclairage (CIE) chromaticity coordinates for WOLEDs is at x=0.33, y=0.33 and it should be insensitive to the applied voltage. In order to achieve this goal, numerous approaches have been explored, such as dye-dispersed poly(N-vinylcarbazole), dye-doped multilayer, dye-doped multilayer structures through interlayer sequential energy transfer, controlling exciton diffusion, triplet excimers in electrophosphorescent material, and blends of polymers. One critical issue in the dye-doped systems is to prevent the single emission from the lower energy dopant resulting from the cascade energy transfer. Ideally, multiple emissions from both the host and the dopants should cover the required spectrum for white light. This can be achieved by controlling the concentration of the dopants and the thickness of the emissive layer or the hole-blocking layer.

Despite recent advances in the development in white light-emitting devices, a need exists for light-emitting devices having substantially pure white light emission. The present invention seeks to fulfill this need and provides further related advantages.

### SUMMARY OF THE INVENTION

The invention provides a light-emitting device, comprising an emissive layer intermediate first and second electrodes, the emissive layer comprising a first compound having emission in the range from about 520 nm to about 600 nm, a second compound having an emission in the range from about 620 to about 720 nm, in an emissive host material having emission in the range from about 420 to about 480 nm. The first compound, the second compound, and the host material each have an absorbance spectrum and an emission spectrum, wherein the emission spectrum of the host material sufficiently overlaps the absorbance spectrum of the first compound to effect energy transfer from the host material to the first compound, and wherein the emission spectrum of the first compound sufficiently overlaps the absorbance spectrum of the second compound to effect energy transfer from the first compound to the second compound. Light produced by the device is substantially pure white light.

In one embodiment, the device further includes an electron transporting layer intermediate the emissive layer and the second electrode.

In one embodiment, the device further includes a hole transporting layer intermediate the first electrode and the emissive layer.

In one embodiment, the device further includes an electron injection layer intermediate the emissive layer and the second electrode.

In one embodiment, the device further includes an electron transporting layer intermediate the emissive layer and the electron injection layer.

In one embodiment, the first compound includes one or more fluorenyl moieties. In one embodiment, the first compound includes one or more 9,9-dialkyl fluorenyl moieties. In one embodiment, the first compound is FFBFF or a derivative thereof.

In one embodiment, the second compound includes one or more fluorenyl moieties. In one embodiment, the second compound includes one or more 9,9-dialkyl fluorenyl moieties. In one embodiment, the second compound is FTBTF or a derivative thereof.

In one embodiment, the host material includes one or more fluorenyl moieties. In one embodiment, the host material comprises one or more 9,9-dialkyl fluorenyl moieties. In one embodiment, the host material is PF-TPA-OXD or derivative thereof.

### BRIEF DESCRIPTION OF THE DRAWINGS

The foregoing aspects and many of the attendant advantages of this invention will become more readily appreciated as the same become better understood by reference to the following detailed description, when taken in conjunction with the accompanying drawings, wherein:

FIG. 1A is the chemical structure of a representative green light-emitting compound useful in the device of the invention: 4,7-bis-(9,9,9′,9′-tetrahexyl-9H,9′H-[2,2′]bifluorenyl-7-yl)-benzo[1,2,5]thiadiazole (FFBFF), when R₁-R₈ are C₆H₁₃;

FIG. 1B is the chemical structure of a representative red light-emitting compound useful in the device of the invention: 4,7-bis-[5-(9,9-dihexyl-9H-fluoren-2-yl)-thiophen-2-yl]-benzo[1,2,5]thiadiazole (FTBTF), when R₉-R₁₂ are C₆H₁₃;

FIG. 1C is the chemical structure of a representative blue light-emitting host compound useful in the device of the invention: poly[(9,9-bis(4-di(4-n-butylphenyl)aminophenyl)]-stat-(9,9-bis(4-(5-(4-tert-butylphenyl)-2-oxadiazolyl)-phenyl))-stat-(9,9-di-n-octyl)fluorene (PF-TPA-OXD), when R₁₃-R₁₆ are C₈H₁₇, R₁₇-R₂₀ are n-butyl, and R₂₁ and R₂₂ are t-butyl;

FIG. 2A is the electroluminescence spectrum of PF-TPA-OXD;

FIG. 2B is the photoluminescence spectrum of FFBFF;

FIG. 2C is the photoluminescence spectrum of FTBTF;

FIG. 2D is the UV-Vis absorbance spectrum of FFBFF;

FIG. 2E is the UV-Vis absorbance spectrum of FTBTF;

FIG. 3A is the electroluminescence spectrum of the emission from a first representative device of the invention (Device 1);

FIG. 3B is the J-V-B curve of the first representative device of the invention (Device 1) with the CIE coordinates of the device at different bias in the inset;

FIG. 4A is the electroluminescence spectrum of the emission from a second representative device of the invention (Device 2);

FIG. 4B is the J-V-B curve of the second representative device of the invention (Device 2) with the CIE coordinates of the device at different bias in the inset; and

FIGS. 5A-5C are schematic illustrations of representative devices of the invention.

### DETAILED DESCRIPTION OF THE PREFERRED EMBODIMENT

In one aspect, the present invention provides a light-emitting electroluminescent device that produces substantially pure white light. The light-emitting device includes an emissive layer intermediate first and second electrodes. The emissive layer includes a first emissive compound having an emission in the range from about 520 nm to about 600 nm (e.g., a green light-emitting compound), a second emissive compound having an emission in the range from about 620 nm to about 720 nm (e.g., a red light-emitting compound), and an emissive host having an emission in the range from about 420 nm to about 480 nm (e.g., a blue light-emitting host). It will be appreciated that emission from the blue light-emitting host and red and green light-emitting compounds occurs as a band of wavelengths having an emission wavelength maximum and an emission bandwidth. Specific wavelengths referred to herein relate to absorbance or emission maxima (nm).

The light-emitting device of the present invention produces substantially white light. In one embodiment, the device produces light having nearly pure white emission. The Commission Internationale d'Enclairage (CIE) chromaticity coordinates of the light produced by an embodiment of the device remain close to that of pure white light at a relatively broad bias range from 6V (x=0.36, y=0.37) to 12V (x=0.34, y=0.34).

The emissive layer of device includes a first emissive compound having an emission in the range from about 520 nm to about 600 nm, a second emissive compound having an emission in the range from about 620 nm to about 720 nm, and an emissive host having an emission in the range from about 420 nm to about 480 nm. The first and second emissive compounds are dispersed in the emissive host.

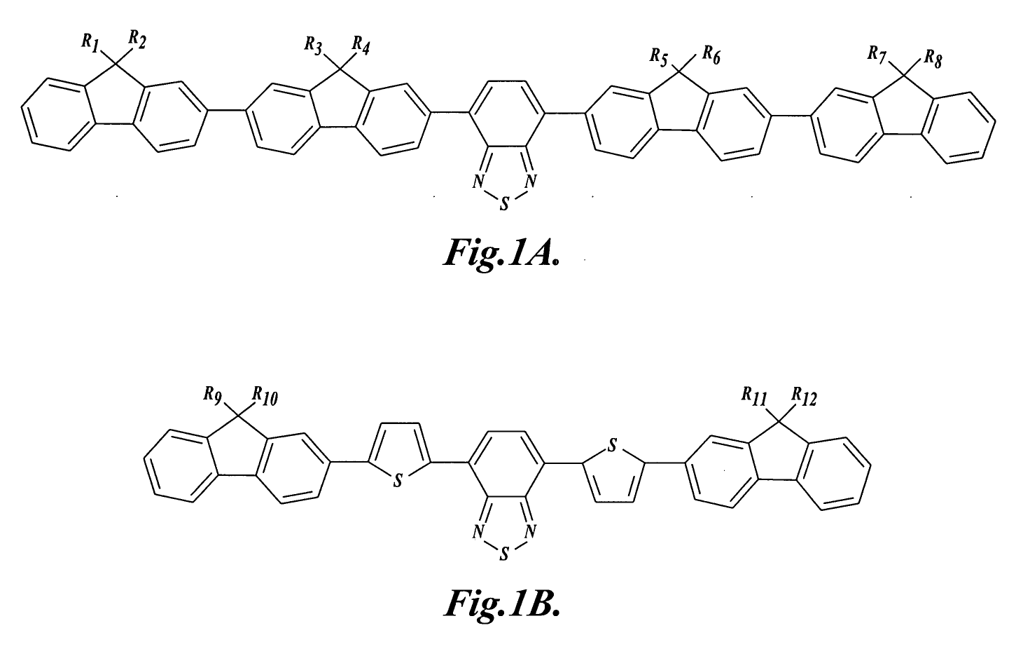

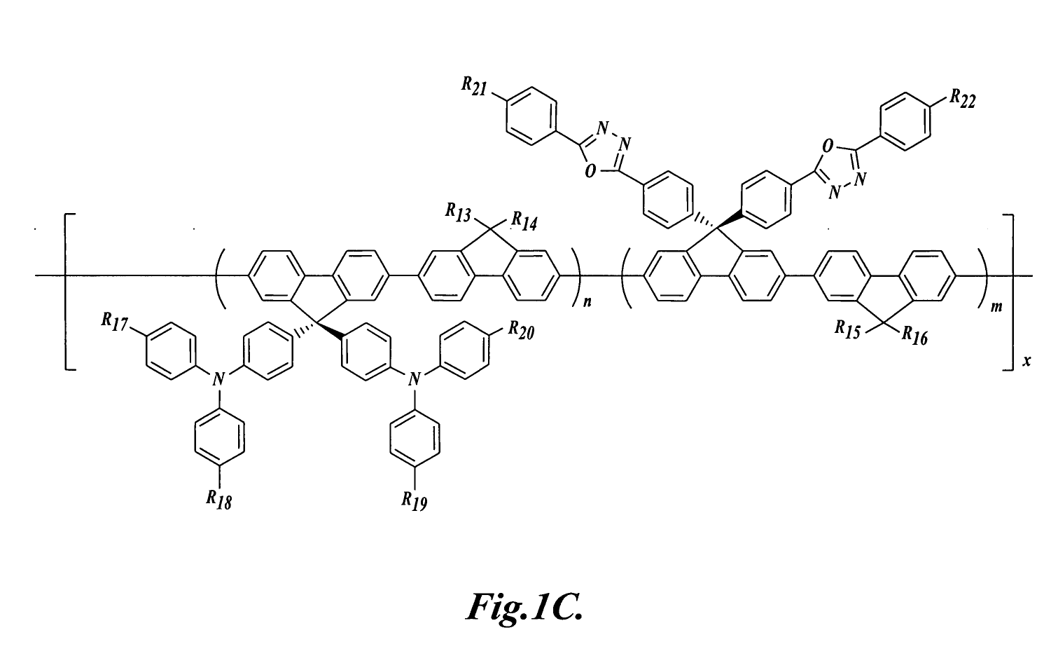

The first emissive compound has an emission in the range from about 520 nm to about 600 nm. In one embodiment, the first compound has an emission in the range from about 540 nm to about 560 nm. In another embodiment, the first compound has an emission of about 550 nm. In general, the first emissive compound is a green light-emitting compound. One representative first emissive compound is 4,7-bis-(9,9,9′,9′-tetrahexyl-9H,9′H-[2,2′]bifluorenyl-7-yl)-benzo[1,2,5]thiadiazole (referred to herein as “FFBFF”). The synthesis of FFBFF is described in Example 1. The chemical structure of representative first emissive compounds is illustrated in FIG. 1A. Referring to FIG. 1A, R₁-R₈ are independently selected from C1-C12 alkyl including substituted alkyl, cycloalkyl, and heteroalkyl, and C5-C10 aryl including heteroaryl. In one embodiment, R₁-R₈ are independently selected from C1-C12 alkyl. In one embodiment, R₁-R₈ are independently selected from C4-C8 alkyl. In one embodiment, R₁-R₈ are n-hexyl (i.e., FFBFF).

Emissive compound FFBFF is a benzo[1,2,5]thiadiazole compound that has been modified to include fluorenyl substituents at positions 4 and 7. FFBFF derivatives can also be used in the emissive layer described herein. Suitable FFBFF derivatives include benzo[1,2,5]thiadiazole compounds that have been modified to include other substituents such as, for example, fluorenyl substituents that are further substituted with additional substituents that do not adversely affect the solubility compatibility of the compound in the emissive layer or the optical properties (e.g., absorbance, emission, energy transfer efficiency) necessary for the emissive layer to emit white light as described herein. Representative substituents include alkyl or aryl substituents at position 9 of the fluorenyl group or at the aromatic positions of the fluorenyl group. It will be appreciated that substitution of the fluorenyl group with other substituents is within the scope of the invention.

The second emissive compound has an emission in the range from about 620 nm to about 720 nm. In one embodiment, the second compound has an emission in the range from about 640 nm to about 670 nm. In another embodiment, the second compound has an emission of about 660 nm. In general, the second emissive compound is a red light-emitting compound. One representative first emissive compound is 4,7-bis-[5-(9,9-dihexyl-9H-fluoren-2-yl)-thiophen-2-yl]-benzo[1,2,5]thiadiazole (referred to herein as “FTBTF”). The synthesis of FTBTF is described in Example 2. The chemical structure of representative second emissive compounds is illustrated in FIG. 1B. Referring to FIG. 1B, R₉-R₁₂ are independently selected from C1-C12 alkyl including substituted alkyl, cycloalkyl, and heteroalkyl, and C5-C10 aryl including heteroaryl. In one embodiment, R₉-R₁₂ are independently selected from C1-C12 alkyl. In one embodiment, R₉-R₁₂ are independently selected from C4-C8 alkyl. In one embodiment, R₉-R₁₂ are n-hexyl (i.e., FTBTF).

Emissive compound FTBTF is a benzo[1,2,5]thiadiazole compound that has been modified to include thiophene substituents at positions 4 and 7, which are further substituted with fluorenyl groups. FTBTF derivatives can also be used in the emissive layer described herein. Suitable FTBTF derivatives include benzo[1,2,5]thiadiazole compounds that have been modified to include other substituents such as, for example, thiophene and/or fluorenyl substituents that are further substituted with additional substituents that do not adversely affect the solubility compatibility of the compound in the emissive layer or the optical properties (e.g., absorbance, emission, energy transfer efficiency) necessary for the emissive layer to emit white light as described herein. Representative substituents include alkyl or aryl substituents at position 9 of the fluorenyl group or at the aromatic positions of the thiophene and/or fluorenyl groups. It will be appreciated that substitution of the thiophene and/or fluorenyl groups with other substituents is within the scope of the invention.

The emissive host has an emission in the range from about 420 nm to about 480 nm. In one embodiment, the host has an emission in the range from about 425 nm to about 450 nm. In general, the emissive host is a blue light-emitting compound. One representative emissive host compound is poly[(9,9-bis(4-di(4-n-butylphenyl)aminophenyl)]-stat-(9,9-bis(4-(5-(4-tert-butylphenyl)-2-oxadiazolyl)-phenyl))-stat-(9,9-di-n-octyl)fluorene (referred to herein as “PF-TPA-OXD”). The synthesis of PF-TPA-OXD is described in Example 3.

The schematic chemical structure of representative hosts is illustrated in FIG. 1C. Referring to FIG. 1C, R₁₃-R₂₂ are independently selected from C1-C12 alkyl including substituted alkyl, cycloalkyl, and heteroalkyl, and C5-C10 aryl including heteroaryl. In one embodiment, R₁₃-R₂₂ are independently selected from C1-C12 alkyl. In one embodiment, R₁₃-R₂₂ are independently selected from C4-C8 alkyl. In one embodiment, R₁₃-R₁₆ are n-octyl, R₁₇-R₂₀ are n-butyl, and R₂₁ and R₂₂ are t-butyl (i.e., PF-TPA-OXD).

A schematic chemical structure of a representative host is illustrated in FIG. 1C. In FIG. 1C, n:m is about 1. As shown in FIG. 1C, the host includes both hole- and electron-transporting moieties as side chains. In the figure, the chemical structure of the host is illustrated schematically and shows a first difluorenyl unit having electron-transporting moieties as side chains (n units) covalently linked to a second difluorenyl unit having hole-transporting moieties as side chains (m units) with the two units together repeating (x units). The representation in FIG. 1C is schematic and generally depicts the copolymer's composition with respect to the repeating units that make up the polymer. It will be appreciated that the copolymer does not necessarily have n units of the first difluorenyl unit having electron-transporting moieties as side chains covalently linked to m units of the second difluorenyl unit having hole-transporting moieties as side chains, with the two units together repeating x times.

Emissive host PF-TPA-OXD is a fluorene-derived copolymer that is obtained from the copolymerization of two monomers. Each monomer includes a first fluorene moiety (i.e., 9,9-di-n-octylfluorenyl group) covalently coupled to a second fluorene moiety. In one monomer, the second fluorene moiety includes hole-transporting moieties (i.e., oxadiazolyl groups). In the other monomer, the second fluorene moiety includes electron-transporting moieties (i.e., triphenyl amine groups). PF-TPA-OXD derivatives can also be used in the emissive layer described herein. Suitable PF-TPA-OXD derivatives include polymers that have been modified to include other substituents such as, for example, fluorenyl and/or phenyl substituents that are further substituted with additional substituents that do not adversely affect the solubility compatibility of the host and the emissive compounds dispersed therein in the emissive layer or the optical properties (e.g., absorbance, emission, energy transfer efficiency) necessary for the emissive layer to emit white light as described herein. Representative substituents include alkyl or aryl substituents at position 9 of the fluorenyl group or at the aromatic positions of the fluorenyl and/or phenyl groups. It will be appreciated that substitution of the fluorenyl and/or phenyl groups with other substituents is within the scope of the invention.

The first and second emissive compounds are compatible with the emissive host. In addition to having appropriate energy transfer, the first and second emissive compounds are suitably soluble in the host material such that phase separation is minimized or substantially avoided. The compatibility of the first and second emissive compounds and host and their suitable solubility is achieved, at least in part, by selection of substituents R₁-R₂₂. For example, compatibility and suitable solubility is achieved when the first emissive compound is FFBFF, the second emissive compound is FTBTF, and the host is PF-TPA-OXD because, in addition to substituents R₁-R₂₂, each of the first and second emissive compounds is a fluorene-derived compound (i.e., includes one or more fluorene moieties) and the host is a polyfluorene-derived copolymer (i.e., includes fluorene-derived repeating units).

In one aspect, the emissive layer includes a green light-emitting compound and a red light-emitting compound, each of which is highly soluble in a blue light-emitting host. The solubility of the green and red light-emitting compounds and the blue light-emitting host can be designed to be compatible and controlled by selection of the structural components (i.e., groups of atoms and/or functional groups) that make up each of the compounds and host. By matching the solubility characteristics of the compounds' and host's structural components, solubility compatibility can be achieved.

The green light-emitting compound and the red light-emitting compound can include one or more structural components compatible with one or more structural components of the host. In one embodiment, the compounds and host have one or more common structural components. In one embodiment, the compounds and host include a common hydrocarbon structural component. In one embodiment, the common structural component is a fluorenyl group. For this embodiment, the green light-emitting compound, the red light-emitting compound, and the blue light-emitting host each include one or more fluorenyl groups. In one embodiment, the fluorenyl group is a 9,9-dialkyl fluorenyl group, such as a 9,9-dihexyl fluorenyl group or a 9,9-dioctyl fluorenyl group. Emissive compounds FFBFF and FTBTF and emissive host PF-TPA-OXD are examples of compounds and hosts having a common structural component (i.e., dialkyl fluorenyl group). Emissive compound FFBFF includes four 9,9-n-dihexylfluorenyl groups; emissive compound FTBTF includes two 9,9-di-n-hexylfluorenyl groups; and host PF-TPA-OXD is a copolymer in which each of the two different repeating units includes a 9,9-di-n-octylfluorenyl group.

In addition to compatibility and suitable solubility, the first and second emissive compounds and host have suitable processability. Processability means that the components (i.e., first and second emissive compounds and host) can be readily processed to provide the emissive layer of a light-emitting device. Suitable processability includes the components being soluble in a solvent or solvents that are useful in making the emissive layer. Suitable solvents for dissolving the components and depositing those components in a manner sufficient to provide the emissive layer. In one embodiment, the components are dissolved in a solvent and spin-coated to provide the emissive layer. Suitable solvents for spin-coating the components include toluene.

In one embodiment, the emissive layer includes from about 0.10 to about 0.30 weight percent of the first emissive compound and from about 0.05 to about 0.15 weight percent of the second emissive compound based on the total weight of the emissive layer. In another embodiment, the emissive layer includes from about 0.15 to about 0.20 weight percent of the first emissive compound and from about 0.08 to about 0.12 weight percent of the second emissive compound based on the total weight of the emissive layer.

In one embodiment, the emissive layer has a thickness of from about 25 to about 100 nm. In one embodiment, the emissive layer thickness is about 50 nm.

A series of efficient and bright white light-emitting diodes were fabricated using the blends of two fluorene-derived fluorescent dyes, 4,7-bis-(9,9,9′,9′-tetrahexyl-9H,9′H-[2,2′]bifluorenyl-7-yl)-benzo[1,2,5]thiadiazole (FFBFF, a green light-emitting compound) and 4,7-bis-[5-(9,9-dihexyl-9H-fluoren-2-yl)-thiophen-2-yl]-benzo[1,2,5]thiadiazole (FTBTF, a red light-emitting compound) in an efficient blue light-emitting polyfluorene-derived copolymer, poly[(9,9-bis(4-di(4-n-butylphenyl)aminophenyl)]-stat-(9,9-bis(4-(5-(4-tert-butylphenyl)-2-oxadiazolyl)-phenyl))-stat-(9,9-di-n-octyl)fluorene (PF-TPA-OXD). The white light-emitting device (ITO/PEDOT/PF-TPA-OXD:FFBFF (0.18 weight percent):FTBTF (0.11 weight percent)/Ca/Ag) reaches a maximum external quantum efficiency of 0.82% and a maximum brightness of 12900 cd/m² at 12 V. The Commission Internationale d'Enclairage (CIE) chromaticity coordinates of the device remain very close to that of pure white emission at a relatively broad bias range from 6V (x=0.36, y=0.37) to 12V (x=0.34, y=0.34).

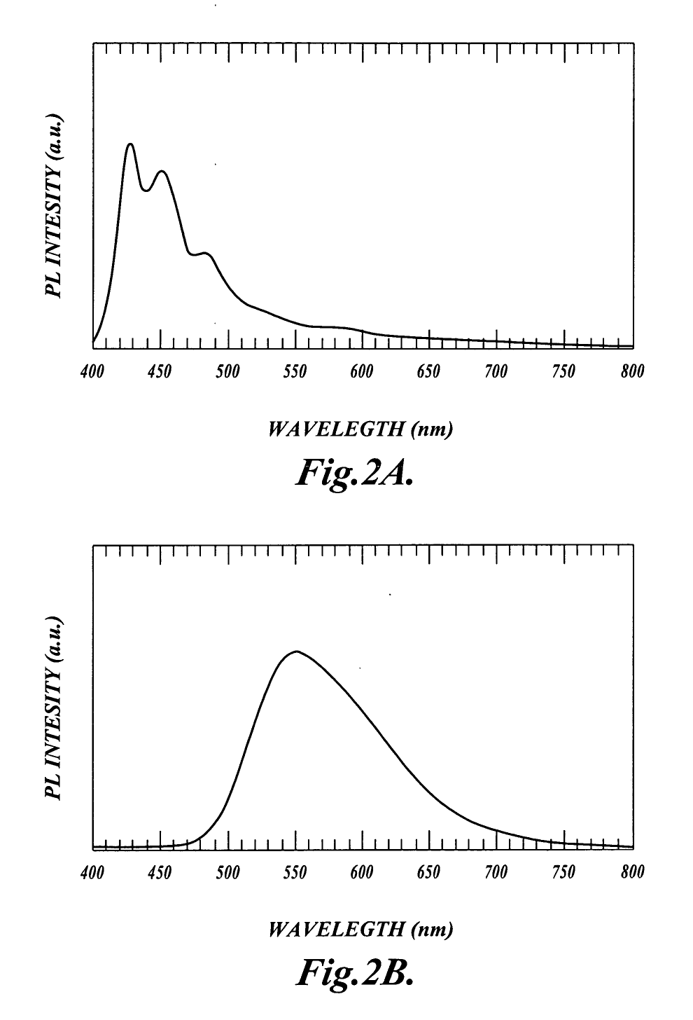

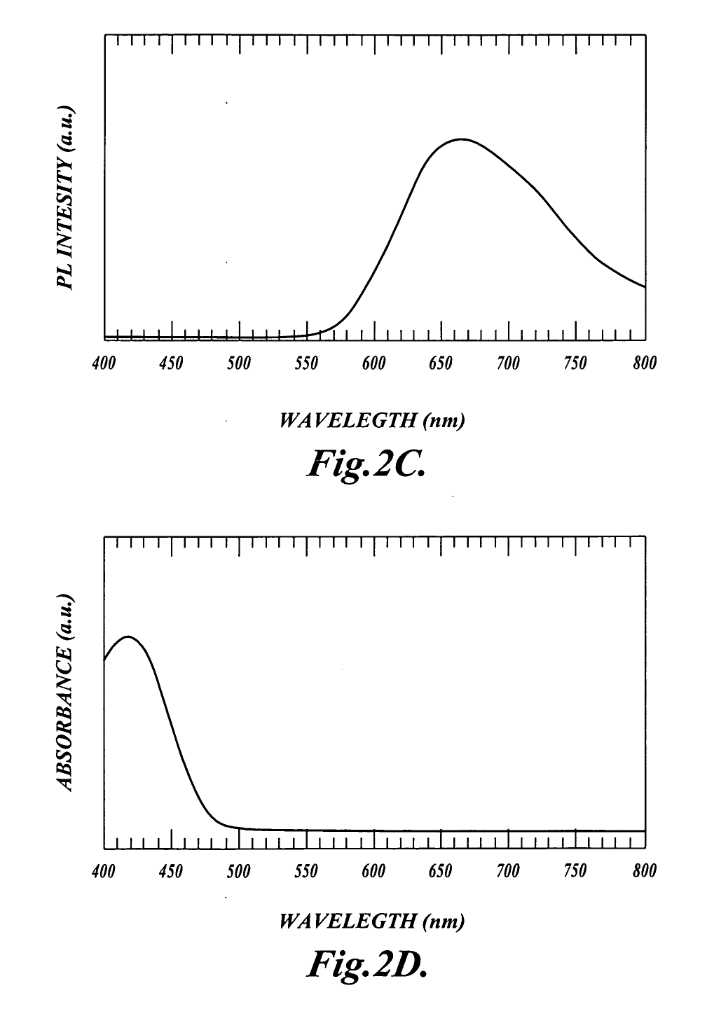

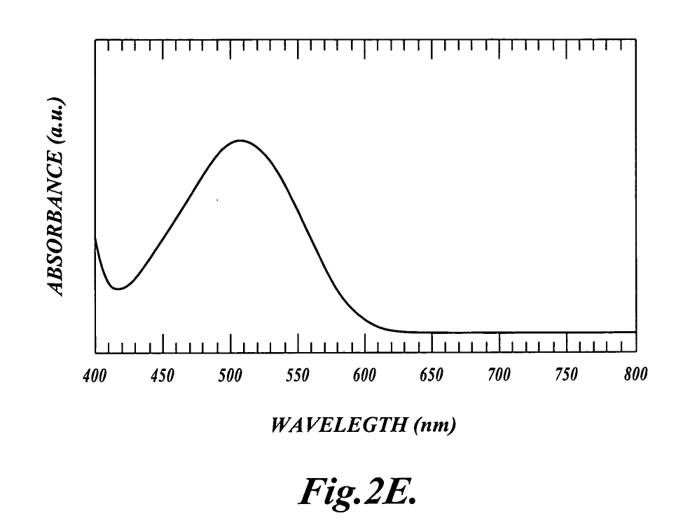

The electroluminescence (EL) spectrum of PF-TPA-OXD is shown in FIG. 2A. Referring to FIG. 2A, the EL spectrum shows the typical emission of polyfluorene with two intense peaks at 425 and 450 nm and a small shoulder peak at 480 nm. The UV-visible (UV-Vis) and photoluminescence (PL) spectra of FFBFF in chloroform solution is shown in FIGS. 2D and 2B, respectively. FIG. 2D shows an absorbance maximum at about 415 nm and FIG. 2B shows an emission maximum at about 550 nm. Both the absorption and emission of FFBFF are red-shifted due to the effect of charge transfer from fluorene to the electron-deficient benzothiadiazole moiety. In addition, the HOMO and LUMO energy levels of FFBFF estimated from the results of cyclic voltammogram and UV-Vis spectrum are −5.73 eV and −3.32, respectively. The UV-Vis and PL spectra of FTBTF in chloroform solution is shown in FIGS. 2E and 2C, respectively. Compared to FFBFF, the peaks of the absorption and emission spectrum of FTBTF are even more red-shifted (506 nm and 660 nm, respectively) because of the stronger charge transfer effect between the electron-donating thiophene rings and the benzothiadiazole in this compound. The HOMO and LUMO energy levels of FTBTF are −5.62 and −3.53 eV, respectively.

In a Forster energy transfer process, the efficiency is proportional to the overlap integral between the emission spectrum of the donor and the absorption spectrum of the acceptor. In principle, the cascade energy transfer (Forster or Dexter type energy transfer) from the host (PF-TPA-OXD) to FFBFF and then to FTBTF should occur because the EL spectrum of PF-TPA-OXD overlaps well with the absorption spectrum of FFBFF (compare FIG. 2A, host emission, with FIG. 2D, FFBFF absorbance) and the PL spectrum of FFBFF also overlaps well with the absorption spectrum of FTBTF (compare FIG. 2B, FFBFF emission, with FIG. 2E, FTBTF absorbance). However, the energy transfer efficiency is also very sensitive to the distance between the donor and the acceptor (∝r⁻⁶). Thus, it is possible to prevent efficient energy transfer by careful control of the FFBFF and FTBTF concentration in PF-TPA-OXD.

As noted above, the emissive layer includes first and second emissive components (e.g., FFBFF and FTBTF) dispersed in an emissive host. These components of the emissive layer cooperate to provide the desired white light emission through energy transfer. Energy transfer occurs through the overlap of the donor emission spectrum and the acceptor absorbance spectrum. In one embodiment, the host has an emission spectrum (see FIG. 2A) having sufficient overlap with the absorbance spectrum of the first emissive compound (see FIG. 2D) to facilitate energy transfer, and the first emissive compound has an emission spectrum (see FIG. 2B) having sufficient overlap with the absorbance spectrum of the second emissive compound (see FIG. 2E) to facilitate energy transfer. White light emission from the emissive layer is achieved by excitation of the host compound that emits blue light and also commences the energy transfer cascade and the emission of green and red light from the first and second emissive compounds, respectively.

In one aspect, the emissive layer includes an electroluminescent host material and first and second emissive compounds. The emission spectrum of the host material overlaps with the absorption spectrum the first emissive compound sufficient to effect energy transfer to and emission from the first emissive compound, and the emission spectrum of the first emissive compound overlaps with the absorption spectrum the second emissive compound sufficient to effect energy transfer to and emission from the second emissive compound. The result is emission from the host material (blue), first emissive compound (green), and second emissive compound (red) that collectively results in white light emission from the emissive layer.

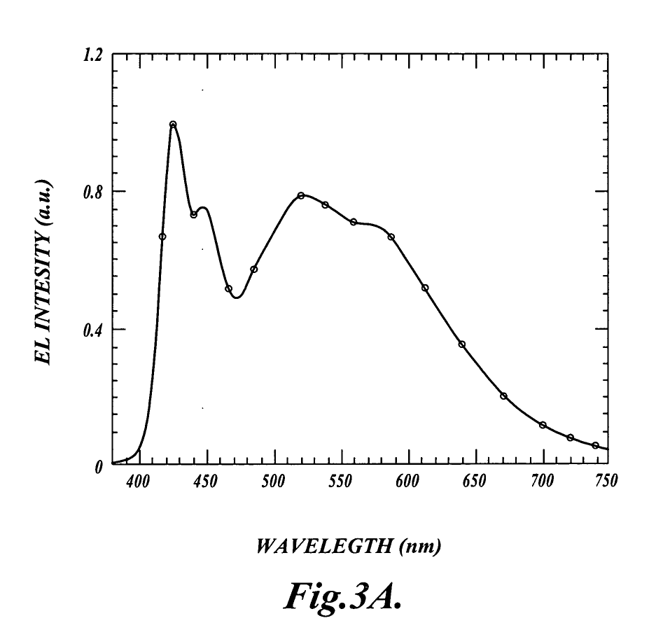

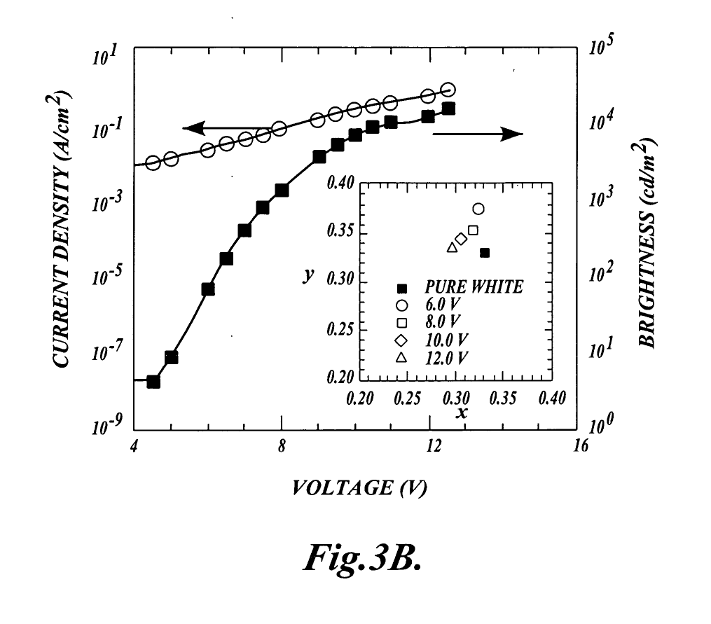

The electroluminescence spectrum of a representative light-emitting device of the invention is shown in FIG. 3A: device having an emissive layer including 0.20 weight percent FFBFF and 0.09 weight percent FTBTF in PF-TPA-OXD (Device 1). Referring to FIG. 3A, the EL spectrum of Device 1 shows the composite emission bands of blue, green, and orange in the whole visible range (400 nm to 750 nm). By comparing the data with the PL spectra of two dyes (FIGS. 2B and 2C), the green-emitting band at 520 nm and the red-emitting band at 586 nm are from the emission of FFBFF and FTBTF, respectively. The CIE coordinate of Device 1 changes slightly from (x=0.30, y=0.34) at 6.0 V to (x=0.32, y=0.38) at 12.0V (See FIG. 3B inset), which is quite insensitive to the applied voltage and is close to that of the ideal CIE chromaticity coordinate for pure white color (i.e., x=0.33, y=0.33). FIG. 3B shows the current density and brightness as a function of the bias voltage (J-V-B). Device 1 shows a relatively low turn-on voltage at 5.0 V (defined as the voltage required to give a luminance of 1 cd/m²). The maximum external quantum efficiency of Device 1 is calculated to be 0.82% at a voltage of 10.0 V and a current density of 0.41 A/cm². The maximum brightness is 15800 cd/m² at a voltage of 12.5 V and a current density of 1.38 A/cm². At this brightness, efficiencies are 0.54%, 1.14 cd/A, and 0.32 lm/W, respectively. At a bias of 7.0 V, the brightness, current density, and external quantum efficiency are 405 cd/m², 0.061 A/cm², and 0.31%, respectively.

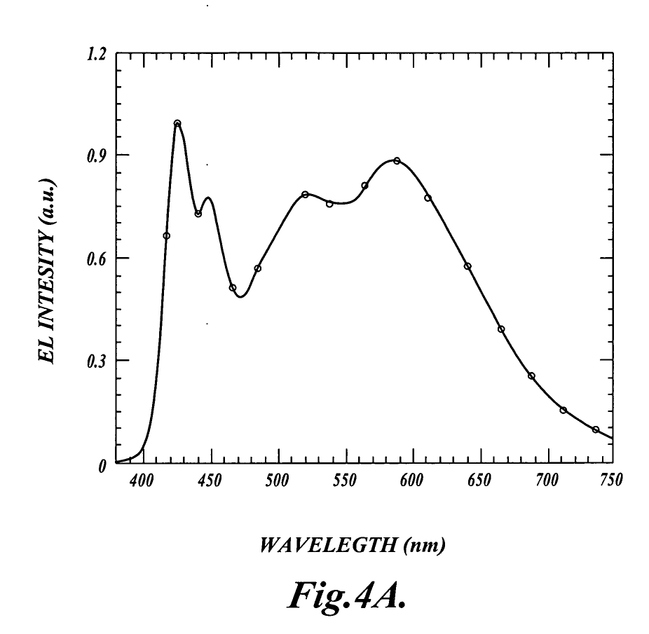

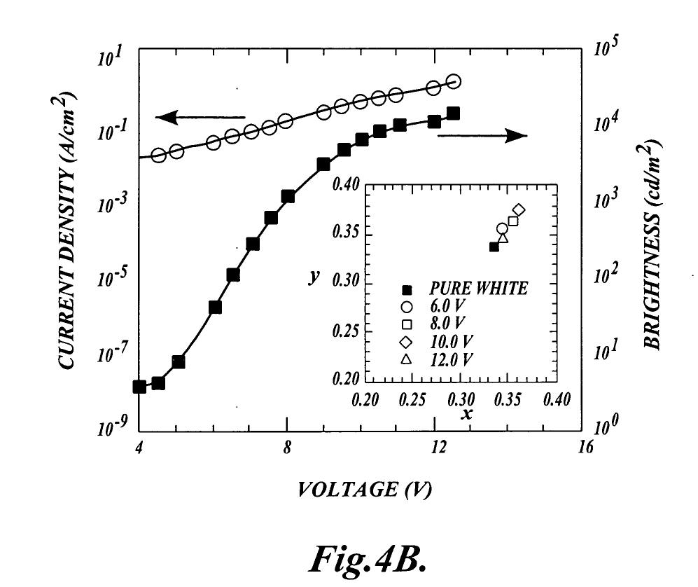

Color purity was improved in a second device (Device 2) having an emissive layer with a slightly adjusted first and second emissive compound concentration (0.18 weight percent FFBFF and 0.11 weight percent FTBTF) in PF-TPA-OXD. The EL spectrum of Device 2 is shown in FIG. 4A. Referring to FIG. 4A, the EL spectrum of Device 1 shows that the EL intensity of FFBFF at 520 nm is decreased and FTBTF at 586 nm is increased, indicating that the spectral change is proportional to the concentration of dyes. As shown in FIG. 4B inset, the CIE coordinate of Device 2 changes from (x=0.36, y=0.37) at 6.0 V to (x=0.34, y=0.34) at 12.0 V, which are also quite insensitive to the applied voltage and are very close to that of the pure white color. As shown in FIG. 4B, the turn-on voltage of Device 2 is the same as that of Device 1. The maximum external quantum efficiency is 0.89% at a voltage of 10.0 V with a current density of 0.41 A/cm². The maximum brightness for white emission as depicted in FIG. 4B is 12900 cd/m² at a voltage of 12.5 V and a current density of 1.23 A/cm². The efficiencies at maximum brightness are 0.61%, 1.05 cd/A, and 0.29 lm/W, respectively. At a bias of 7.0 V, the brightness, current density, and external quantum efficiency are 263 cd/m², 0.056 A/cm², and 0.27%, respectively. The CIE coordinate of both devices shifted slightly toward blue-emitting region when the applied voltage was increased. This is because that at higher voltages, the high-energy states in the blend start to get populated because most of the low energy states have already been filled. This also increases the relative intensity of blue emission. The EL maximum of FFBFF and FTBTF are blue-shifted compared to their PL maxima in chloroform due to the solid-state solvation effect (SSSE).

Devices 1 and 2 described above are double layer devices prepared as described in Example 4.

In another aspect, the present invention provides light-emitting devices that include the emissive layer described above. Devices comprising the present compounds have advantageous properties as compared with known devices. High external quantum and luminous efficiencies can be achieved in the present devices. Device lifetimes are also generally better than, or at least comparable to, some of the most stable fluorescent devices reported.

Typical devices are structured so that one or more layers are sandwiched between a hole injecting anode layer and an electron injecting cathode layer. The sandwiched layers have two sides, one facing the anode and the other facing the cathode. Layers are generally deposited on a substrate, such as glass, on which either the anode layer or the cathode layer may reside. In some embodiments, the anode layer is in contact with the substrate. In some embodiments, for example when the substrate comprises a conductive or semi-conductive material, an insulating material can be inserted between the electrode layer and the substrate. Typical substrate materials, that may be rigid, flexible, transparent, or opaque, include glass, polymers, quartz, sapphire, and the like.

In some embodiments, devices of the invention include layers in addition to the emissive layer. For example, in addition to the electrodes, devices can include any one or more hole blocking layers, electron blocking layers, exciton blocking layers, hole transporting layers, electron transporting layers, hole injection layers, or electron injection layers. Anodes can include an oxide material such as indium-tin oxide (ITO), Zn—In—SnO₂, SbO₂, or the like, and cathodes can include a metal layer such as Mg, Mg:Ag, or LiF:Al. Among other materials, the hole transporting layer (HTL) can include triaryl amines or metal complexes. Similarly, the electron transporting layer (ETL) can include, for example, aluminum tris(8-hydroxyquinolate) (Alq₃) or other suitable materials. A hole injection layer can include, for example, 4,4′,4″-tris(3-methylphenylphenylamino)triphenylamine (MTDATA), polymeric material such as poly(3,4-ethylenedioxythiophene) (PEDOT), or metal complex such as, for example, copper phthalocyanine (CuPc), or other suitable materials. Hole blocking, electron blocking, and exciton blocking layers can include, for example, BCP, BAlq, and other suitable materials such as FIrpic or other metal complexes.

Light emitting devices of the invention can be fabricated by a variety of techniques well known to those skilled in the art. Small molecule layers can be prepared by vacuum deposition, organic vapor phase deposition (OVPD), or solution processing such as spin coating. Polymeric films can be deposited by spin coating and chemical vapor deposition (CVD). Layers of charged compounds, such as salts of charged metal complexes, can be prepared by solution methods such a spin coating or by an OVPD method such as disclosed in U.S. Pat. No. 5,554,220, expressly incorporated herein by reference in its entirety. Layer deposition generally, although not necessarily, proceeds in the direction of the anode to the cathode, and the anode typically rests on a substrate. Devices and techniques for their fabrication are described throughout the literature and in, for example, U.S. Pat. Nos. 5,703,436; 5,986,401; 6,013,982; 6,097,147; and 6,166,489, each expressly incorporated herein by reference in its entirety. For devices from which light emission is directed substantially out of the bottom of the device (i.e., substrate side), a transparent anode material such as ITO may be used as the bottom electron. Because the top electrode of such a device does not need to be transparent, such a top electrode, which is typically a cathode, may be comprised of a thick and reflective metal layer having a high electrical conductivity. In contrast, for transparent or top-emitting devices, a transparent cathode may be used such as disclosed in U.S. Pat. Nos. 5,703,436 and 5,707,745, each expressly incorporated herein by reference in its entirety. Top-emitting devices may have an opaque and/or reflective substrate, such that light is produced substantially out of the top of the device. Devices can also be fully transparent, emitting from both top and bottom.

Transparent cathodes, such as those used in top-emitting devices preferably have optical transmission characteristics such that the device has an optical transmission of at least about 50%, although lower optical transmissions can be used. In some embodiments, devices include transparent cathodes having optical characteristics that permit the devices to have optical transmissions of at least about 70%, 85%, or more. Transparent cathodes, such as those described in U.S. Pat. Nos. 5,703,436 and 5,707,745, typically include a thin layer of metal such as Mg:Ag with a thickness, for example, that is less than about 100 Angstrom. The Mg:Ag layer can be coated with a transparent, electrically-conductive, sputter-deposited, ITO layer. Such cathodes are often referred to as compound cathodes or as TOLED (transparent-OLED) cathodes. The thickness of the Mg:Ag and ITO layers in compound cathodes may each be adjusted to produce the desired combination of both high optical transmission and high electrical conductivity, for example, an electrical conductivity as reflected by an overall cathode resistivity of about 30 to 100 ohms. However, even though such a relatively low resistivity can be acceptable for certain types of applications, such a resistivity can still be somewhat too high for passive matrix array OLED pixels in which the current that powers each pixel needs to be conducted across the entire array through the narrow strips of the compound cathode.

Light emitting devices of the present invention can be used in a pixel for an electronic display. Virtually any type of electronic display can incorporate the present devices. Displays can include computer monitors, televisions, personal digital assistants, printers, instrument panels, bill boards, and the like. In particular, the present devices can be used in flat panel displays and heads-up displays.

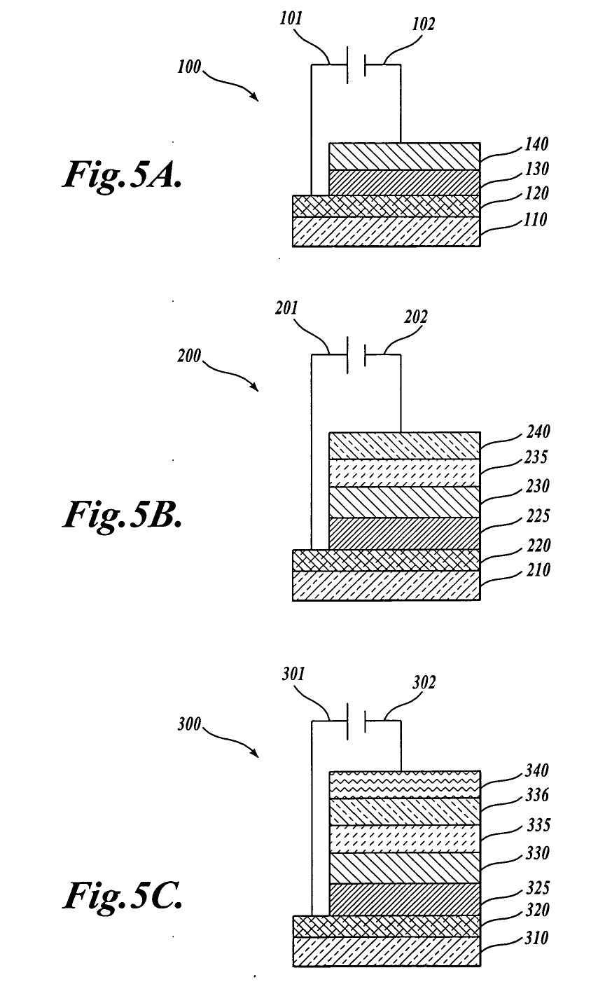

In one embodiment, the device is a single-layer device. In other embodiments, the device includes more than one layer, for example, a double-layer device or a triple-layer device. Representative devices of the invention are illustrated in FIGS. 5A-5C.

A single layer device (an electroluminescent cell) is illustrated in FIG. 5A. Referring to FIG. 5A, representative device 100 includes first substrate layer 110, indium-tin oxide (ITO) anode layer 120, emissive layer 130, electron transporting and protective layer 140, first electrode 101, and second electrode 102. In the device, the first substrate layer can be a glass substrate layer, and the electron transporting/protective layer can be a layer that includes gold.

A double layer device is illustrated in FIG. 5B. Referring to FIG. 5B, representative device 200 includes first substrate layer 210, indium-tin oxide (ITO) anode layer 220, hole-transporting material layer 225, emissive layer 230, electron injection cathode layer 235, protective layer 240, first electrode 201, and second electrode 202. In the device, the first substrate layer can be a glass substrate layer, and the protective layer can include aluminum, gold, or silver. The electron injection cathode layer can include calcium. Thus, in one embodiment, the invention provides a double layer device having a hole-transport layer, an emissive layer as described above, and an electron injection cathode layer.

A triple layer device is illustrated in FIG. 5C. Referring to FIG. 5C, representative device 300 includes first substrate layer 310, indium-tin oxide (ITO) anode layer 320, hole-transporting material layer 325, emissive layer 330, electron transporting layer 335, electron injection cathode layer 336, protective layer 340, first electrode 301 and second electrode 302. In the device, the first substrate layer can be a glass substrate layer, and the protective layer can include aluminum, silver, or gold. The electron transporting layer can include aluminum tris(8-hydroxyquinolate) (Alq₃), and the electron injection cathode layer can include lithium fluoride. Thus, in one embodiment, the invention provides a triple layer device having a hole-transport layer, an emissive layer as described above, an electron transporting layer, and an electron injection cathode layer.

In summary, the invention provides a bright white light-emitting device having an emissive layer that includes a dispersion of two fluorene-derived compounds (i.e., a first, green light-emitting compound and a second, red light-emitting compound) in a polyfluorene-based copolymer (i.e., a blue light-emitting host compound). Through a balanced charge injection and transport of the host polymer and the carefully controlled dye concentrations, the resulting devices reach high external quantum efficiency and brightness of 0.82%, 15800 cd/m² and 0.89%, 12900 cd/m², respectively. The devices also show relatively high efficiency and brightness at low applied voltages. The chromaticity coordinates of these devices are very close to that of the pure white color and remain very stable at a relatively wide bias range from 6.0 to 12.0 V.

The following examples are provided for the purpose of illustrating, not limiting, the present invention.

### EXAMPLES

### Example 1

### The Synthesis of a Representative First Emissive Compound: FFBFF

In the example, the synthesis of a representative first emissive compound, 4,7-bis-(9,9,9′,9′-tetrahexyl-9H,9′H-[2,2′]bifluorenyl-7-yl)-benzo[1,2,5]thiadiazole (FFBFF), a green light-emitting compound, useful in the device of the invention is described.

9,9-Dihexyl fluorene. Fluorene (10 g, 60 mmol) was dissolved in absolute THF and set under nitrogen. The solution was cooled to 0° C. and nBuLi (26 mL, 65 mmol) was added dropwise at this temperature. The solution was kept at this temperature for an additional 2 h. Bromohexane (9.3 mL, 65 mmol) was added dropwise at this temperature and the solution was allowed to thaw overnight. The orange solution was quenched with water and stirred for an additional 2 hours at room temperature. The THF was evaporated and the residue was redissolved in water and hexanes. The layers were separated and the aqueous layer was further extracted with hexanes. All organic layers were combined, dried over sodium sulfate and the solvent was evaporated. The crude product was filtered through silica gel with hexanes as eluent to yield a clear oil, which was dried at vacuum overnight. The clear oil (10 g, 60 mmol) was dissolved in absolute THF and set under nitrogen. The solution was cooled to 0° C. and nBuLi (26 mL, 65 mmol) was added dropwise at this temperature. The solution was kept at this temperature for an additional 2 h. Bromohexane (9.3 mL, 65 mmol) was added dropwise at this temperature and the solution was allowed to thaw overnight. The orange solution was quenched with water and stirred for an additional 2 hours at room temperature. The THF was evaporated and the residue was redissolved in water and hexanes. The layers were separated and the aqueous layer was further extracted with hexanes. All organic layers were combined, dried over sodium sulfate and the solvent was evaporated. The crude product was filtered through silica gel with hexanes as eluent to yield 18 g (89%) of a clear oil, which crystallized after one week. M.P. 31-33° C. (Lit: 32-34° C.); ¹H-NMR (300 MHz, CDCl₃) δ (ppm): 0.74 (t, J=6.6 Hz, 6H), 1.00-1.12 (m, 16H), 1.92 (t, J=4.2 Hz, 2H), 1.95 (t, J=4.2 Hz, 2H), 7.26-7.34 (m, 6H), 7.69-7.66 (m, 2H); ¹³C-NMR (75 MHz, ¹H-decoupled, CDCl₃) δ (ppm): 14.34, 22.92, 24.07, 30.09, 31.85, 40.78, 55.34, 119.96, 123.16, 126.92, 127.41, 141.46, 151.02.

2,7-Dibromo-9,9-dihexyl fluorene. 9,9-Dihexyl fluorene (7.5 g, 21 mmol) was dissolved in dry DMF (35 mL). A crystal of iodine was added followed by the slow addition of bromine (4.2 mL, 82 mmol). The solution was stirred at room temperature overnight under the exclusion of light. Then the solution was cooled to 110° C. in a water bath and a 10% solution of potassium hydroxide in water (20 mL) was added slowly. The layers were separated and the aqueous layer was extracted with hexanes. All organic layers were combined, washed with water until neutral and dried over sodium sulfate. The solvent was removed under reduced pressure. The crude product was filtered through silica gel with hexanes as eluent. The obtained oil was set to crystallize, followed by recrystallization from hexanes/ethanol (1:1) and hexanes to yield 10.5 g (90%) of a white solid. M.P. 64-66° C. (Lit: 66-68° C.); ¹H-NMR (300 MHz, CDCl₃) δ (ppm): 0.79 (t, J=6.6 Hz, 6H), 0.98-1.18 (m, 16H), 1.91 (t, J=4.2 Hz, 2H), 1.93 (t, J=4.2 Hz, 2H), 7.45 (s, 2H), 7.46 (dd, J=7.5 Hz, 2.1 Hz, 2H), 7.53 (dd, J=7.5 Hz, 0.6 Hz, 2H); ¹³C-NMR (75 MHz, ¹H-decoupled, CDCl₃) δ (ppm): 14.45, 23.02, 24.08, 30.02, 31.89, 40.64, 56.12, 121.54, 121.94, 126.62, 130.59, 152.97.

(9,9-Dihexyl-9H-2,7-fluorene-ylene)bis-1,3,2-dioxoborolane. 2,7-Dibromo-(9,9-dihexyl fluorene) (14 g, 29 mmol) was dissolved in dry THF (150 mL) and set under nitrogen. The solution was cooled to −78° C. and tBuLi (76 mL, 130 mmol) was added dropwise at this temperature. The solution was stirred for an additional two hours at this temperature. Trimethylborate (7.5 mL, 66 mmol) was added at once at −78° C. and the solution was allowed to thaw overnight. The solution was quenched slowly with 2M hydrochloric acid (80 mL). The solution was stirred for an additional six hours at room temperature. Then the THF was evaporated under reduced pressure and the residue was mixed with ether. The organic layer was separated, and the aqueous layer was extracted with additional ether. All organic layers were combined, washed once with water and dried over sodium sulfate. The ether was evaporated at vacuum resulting in slightly yellow crystals. The solid was purified using flash column chromatography (silica gel) with toluene/methanol (30:1) as eluent. The resulting crystals were dissolved in absolute toluene and heated to reflux. Ethylene glycol (3.4 mL, 61 mmol) was added at once and the solution was continued to reflux. The water was distilled out using a Dean-Stark trap. The solution was cooled to room temperature, washed with water, and dried over sodium sulfate and the solvent was evaporated under reduced pressure. The crude oil was purified by flash column chromatography with toluene/methanol (30:1) as eluent. Further purification was done by recrystallization from hexanes to yield 9.2 g (68%) of a white powder. M.P. 120-122° C.; ¹H-NMR (300 MHz, CDCl₃) δ (ppm): 0.75 (t, 6H, J=7.0 Hz), 0.98-1.10 (m, 16H), 1.98 (dt, 4H, J=4.2 Hz), 4.40 (s, 8H), 7.72-7.83 (m, 6H); ¹³C-NMR (75 MHz, ¹H-decoupled, CDCl₃) δ (ppm): 14.21, 22.72, 23.90, 29.84, 31.68, 40.50, 55.20, 66.15, 119.80, 126.63, 129.24, 133.81, 144.15, 150.67.

2-Bromo-9,9-dihexylfluorene. 2-Bromofluorene (10.0 g, 41 mmol), n-bromohexane (13.3 mL, 94 mmol) and tetrapentyl ammonium bromide (0.15 g, 0.40 mmol) were dissolved into toluene (90 mL). A 50 wt % solution of sodium hydroxide in water (90 mL) was added at once and the solution was stirred at 60° C. over night. The solution was cooled to room temperature, diluted with ethyl acetate and the layers were separated. The aqueous layer was extracted three times with ethyl acetate. All organic layers were combined, washed with water until neutral and dried over sodium sulfate. The solvent was evaporated under reduced pressure and the crude oil was purified by silica gel flash column chromatography with hexanes as eluent to yield 11.8 g (70%) of a clear oil. ¹H-NMR (300 MHZ, CDCl₃) δ (ppm): 0.75 (t, J=7.2 Hz, 6H), 0.97-1.32 (m, 16 Hz), 1.88-1.95 (m, 4H), 7.28-7.33 (m, 3H), 7.42 (dd, J=7.2 Hz, 2.4 Hz, 1H), 7.43 (s, 1H), 7.53 (dd, J=7.2 Hz, 1.5 Hz, 1H), 7.63-7.66 (m, 1H); ¹³C-NMR (75 MHz, ¹H-decoupled, CDCl₃) δ (ppm): 14.33, 22.90, 23.99, 29.96, 31.81, 40.63, 55.69, 120.06, 121.27, 121.33, 123.18, 126.43, 127.47, 127.78, 130.81, 140.34, 140.47, 150.74, 153.28.

(9′,9′-Dihexyl-2′-fluorene-yl)boronic acid. 2-Bromo-9,9-dihexylfluorene (17 g, 41 mmol) was set under nitrogen and dissolved in THF. The solution was cooled to −78° C. tBuLi (53 ml, 90 mmol) was added dropwise at this temperature and the solution was stirred at this temperature for two hours. Trimethyl borate (5.2 ml, 45 mmol) was added at once and the solution was thawed over night. The solution was quenched with 2M hydrochloric acid (160 mL) and stirred over night again. The THF was removed under reduced pressure and the aqueous layer was extracted with diethyl ether. All organic layers were combined, washed with water until neutral and dried over sodium sulfate. The ether was evaporated under reduced pressure and the remaining oil was dried at vacuum. The compound was purified via a silica gel flash column with hexanes/methylene chloride (70/30) as eluent to yield a slightly-yellow oil which crystallized after standing. The crystals were recrystallized from hexanes to yield 11 g (72%) of white crystals. M.P. 73-75° C.; ¹H-NMR (300 MHz, CDCl₃) δ (ppm): 0.78 (t, J=6.9 Hz, 6H), 1.00-1.21 (m, 12H), 1.24-1.37 (m, 4H), 1.90 (t, J=4.7 Hz, 2H), 1.94 (t, J=4.7 Hz, 2H), 4.82 (s, 2H), 6.78-6.83 (m, 2H), 7.23-7.32 (m, 3H), 7.54-7.61 (m, 2H); ¹³C-NMR (75 MHz, ¹H-decoupled, CDCl₃) δ (ppm): 110.44, 114.22, 119.09, 120.84, 122.97, 126.25, 127.00, 134.65, 141.27, 150.44, 153.40, 155.44.

2,1,3-Benzothiadiazole. 1,2-Phenylenediamine (20 g, 185 mmol) was dissolved in dry toluene (400 mL) and pyridine (60 mL, 740 mmol). The solution was heated to reflux and thionyl chloride (32 mL, 440 mmol) was added dropwise at this temperature. Water was removed overnight using a Dean-Stark trap. The solution was cooled to RT and poured onto ice (400 mL). The layers were separated and the organic layer was washed with water until neutral, dried over sodium sulfate, and the toluene was evaporated under reduced pressure. The crude product was purified via flash column chromatography with hexanes/methylene chloride (3:2) as eluent to yield 8.8 g (35%) of white crystals. M.P. 44-46° C.; ¹H-NMR (200 MHz, CDCl₃) δ (ppm): 7.58 (dd, J=6.6 Hz, 3.1 Hz, 2H), 8.00 (dd, J=6.6 Hz, 3.1 Hz, 2H); ¹³C-NMR (75 MHz, ¹H-decoupled, CDCl₃) δ (ppm): 121.54, 129.27, 154.79.

4,7-Dibromo-2,1,3-benzothiadiazol. 2,1,3-Benzothiadiazol (1.5 g, 11 mmol) was dissolved in hydrobromic acid (48% in water, 20 mL) and the mixture was heated to reflux. Bromine (1.3 mL, 24 mmol) was added under these conditions and the solution was continued to reflux over night. The solution was filtered hot and the filtrate was cooled in an ice bath. The precipitate formed was filtered off, washed with water, saturated sodium carbonate solution and water until neutral. The crude product was recrystallized from hexanes to yield 1.4 g (43%) of white crystals. M.P. 181-183° C. (Lit: 184-185° C.); ¹H-NMR (300 MHz, CDCl₃) δ (ppm): 7.71 (s, 2H); ¹³C-NMR (75 MHz, ¹H-decoupled, CDCl₃) δ (ppm): 114.12, 132.53, 153.16.

4,7-Bis(9′,9′-dihexyl-2′-fluorene-yl)-1,3,2-benzothiadiazole (FBF). 4,7-Dibromo-1,3,2-benzothiadiazole (0.92 g, 3.1 mmol), (9,9-dihexyl-2-fluorene-yl)boronic acid (3.0 g, 7.8 mmol), palladium tetrakistriphenylphosphine (0.035 g, 0.030 mmol) and ALIQUAT 336 (0.57 g, 1.4 mmol) were set under nitrogen. Toluene was added and the solution was heated to 80° C. A 2 M potassium carbonate solution (12 mL, 26 mmol) was added at once and the mixture was refluxed overnight and then cooled to room temperature. The toluene layer was separated and the aqueous layer was extracted with methylene chloride. All organic layers were combined, washed with water until neutral and dried over sodium sulfate. The solvent was evaporated under reduced pressure. The yellow oil was purified via silica gel flash column chromatography with hexane/methylene chloride (5%) as an eluent to yield 2.1 g (81%) of a yellow solid. M.P. 107-109° C.; MS (FAB) m/z 801.5 (cal. m/z 800.51); ¹H NMR (300 MHz, CDCl₃) δ (ppm): 0.73 (t, J=6.3 Hz, 12H), 0.99-1.13 (m, 32H), 1.86-2.04 (m, 8H), 7.28-7.37 (m, 6H), 7.74 (dd, J=5.7 Hz, 1.5 Hz, 2H), 7.84 (d, J=8.7 Hz, 2H), 7.85 (s, 2H), 7.91 (d, J=1.2 Hz, 2H), 7.99 (dd, J=7.8 Hz, 1.2 Hz, 2H); ¹³C NMR (75 MHz, ¹H decoupled, CDCl₃) δ (ppm): 14.23, 22.77, 24.06, 29.95, 31.69, 40.53, 55.40, 119.90, 120.13, 123.11, 124.13, 127.04, 127.44, 128.05, 128.33, 133.73, 136.36, 140.84, 141.50, 151.24, 151.48, 154.55; Elemental anal. calc. for C₅₆H₆₈N₂S: C, 83.95; H, 8.55; N, 3.50; S, 4.00; found: C, 84.04; H, 8.67; N, 3.56.

4,7-Bis(7′-bromo-9′,9′-dihexyl-2-fluoren-yl)-1,3,2-benzothiadiazole (BrFBFBr). FBF (2.0 g, 2.5 mmol) was suspended in DMF (40 mL). Bromine (0.51 mL, 10 mmol) was added at once and the suspension was stirred overnight at room temperature under the exclusion of light. Then the orange suspension was quenched with a 10 wt % solution of sodium thiosulfate and stirred for one additional hour. A bright yellow precipitate formed, which was filtered by suction, washed with additional sodium thiosulfate solution and then with water. The solid was dried under vacuum overnight. The compound was purified via silica gel flash column chromatography with hexane/methylene chloride (5%) as eluent. The resulting powder was further recrystallized from hexane, filtered and dried under vacuum to yield 1.83 g (76%) of a bright yellow solid. M.P. 188-190° C.; MS (FAB) m/z 958.34 (cal. m/z 958.33); ¹H NMR (300 MHz, CDCl₃) δ (ppm): 0.76 (t, J=6.6 Hz, 12H), 1.07-1.24 (m, 16H), 1.88-1.22 (m, 8H), 7.46 (d, J=1.5 Hz, 1H), 7.49 (s, 3H), 7.61 (d, J=8.7 Hz, 2H), 7.81 (d, J=7.5 Hz, 2H), 7.86 (s, 2H), 7.92 (d, J=0.9 Hz, 2H), 7.99 (dd, J=7.8 Hz, 1.5 Hz, 2H); ¹³C NMR (75 MHz, ¹H decoupled, CDCl₃) δ (ppm): 14.23, 22.78, 24.03, 29.88, 31.68, 40.42, 55.77, 120.04, 121.48, 121.55, 124.18, 126.47, 128.08, 128.52, 130.28, 133.67, 136.77, 139.88, 140.42, 150.91, 153.74, 154.47; Elemental anal. calc. for C₅₆H₆₆Br₂N₂S: C, 70.13; H, 6.94; Br, 16.66; N, 2.92; S, 3.34; found: C, 70.45; H, 6.96; N, 3.03.

4,7-Bis[7′-(7′-(9″,9″-dihexyl-fluorene-2″-yl)-9′,9′-dihexyl-2′-fluorenylene]-1,3,2-benzothiadiazole (FFBFF). 4,7-Bis(7′-bromo-9′,9′-dihexyl-2-fluoren-yl)-1,3,2-benzothiadiazole (0.30 g, 0.32 mmol), (9,9-dihexyl-2-fluorene-yl)boronic acid (0.36 g, 0.95 mmol), palladium tetrakis(triphenyl)phosphine (0.011 g, 0.0096 mmol), and potassium carbonate (500 mg, 1.9 mmol) were set under nitrogen and dissolved into DMF (30 mL). The solution was heated to 80° C. and water (1 mL) was added at once. The solution was heated to 105° C. and kept at this temperature for 30 hours. Then the solution was cooled to room temperature and the DMF was removed under reduced pressure. The residue was taken into a methylene chloride/water mixture. The layers were separated and the organic layer was washed extensively with water, dried over sodium sulfate and the methylene chloride was evaporated. The crude product was dried at air overnight and purified via silica gel flash column chromatography with hexane/methylene chloride (20%) as eluent to yield 0.18 g (38%) of a yellow powder. M.P. 158-160° C.; ¹H NMR (300 MHz, CDCl₃) δ (ppm): 0.76 (t, J=6.4 Hz, 18H), 0.78-0.86 (m, 16H), 1.03-1.20 (m, 48H), 1.95-2.11 (m, 16H), 7.33-7.40 (m, 6H), 7.48 (dd, J=1.2 Hz, 8.0 Hz, 2H), 7.50 (s, 2H), 7.62 (d, J=8.6 Hz, 2H), 7.83 (d, J=7.6 Hz, 4H), 7.88 (s, 4H), 7.94 (m, 4H), 8.01 (d, J=7.8 Hz, 4H); ¹³C-NMR (75 MHz, ¹H-decoupled, CDCl₃) δ (ppm): 14.39, 22.94, 24.20, 30.02, 31.82, 40.57, 40.67, 55.55, 55.90, 119.88, 120.36, 120.46, 120.56, 121.68, 121.91, 123.03, 123.52, 124.00, 124.56, 126.84, 127.92, 128.76, 128.99, 130.14, 130.67, 133.72, 134.00, 136.46, 137.00, 139.99, 140.97, 151.05, 151.41, 151.64, 153.89, 154.61, 154.68.

### Example 2

### The Synthesis of a Representative Second Emissive Compound: FTBTF

In the example, the synthesis of a representative second emissive compound, 4,7-bis-[5-(9,9-dihexyl-9H-fluoren-2-yl)-thiophen-2-yl]-benzo[1,2,5]thiadiazole (FTBTF), a red light-emitting compound, useful in the device of the invention is described.

4,7-Bis(2′-thienyl)-1,3,2-benzothiadiazole (TBT). Thiophene boronic acid (0.93 g, 7.0 mmol), 2,7-dibromobenzothiadiazole (0.58 g, 2.0 mmol), palladium tetrakis (triphenylphosphine) (0.020 g, 0.017 mmol) and ALIQUAT 336 (0.081, 0.20 mmol) were set under nitrogen, and then dissolved in dry toluene (15 mL). The mixture was heated to 80° C. and a 2 M solution of potassium carbonate (8.2 mL, 16 mmol) was added at once. The solution was stirred at 100° C. for three days, and then cooled to room temperature. The toluene was evaporated under reduced pressure. The remaining oil was redissolved into methylene chloride and quenched with water. The organic layer was separated, and the aqueous layer was extracted with additional methylene chloride. All organic layers were combined, washed with water until neutral and dried over sodium sulfate. The methylene chloride was evaporated under reduced pressure and the dark red oil was purified via silica gel flash column chromatography with hexane/methylene chloride (10%) as eluent to afford 0.11 g (18%) of an orange solid. M.P. 119-121° C. (Lit: 121-123° C.); MS (FAB) m/z 300.0 (cal. m/z 299.98); ¹H NMR (300 MHz, CDCl₃) δ (ppm): 7.20 (dd, J=5.1 Hz, 3.6 Hz, 2H), 7.44 (dd, J=5.1 Hz, 1.5 Hz, 2H), 7.86 (s, 2H), 8.10 (dd, J=3.6 Hz, 0.9 Hz, 2H); ¹³C NMR (75 MHZ, ¹H decoupled, CDCl₃) δ (ppm): 125.92, 126.14, 126.97, 127.69, 128.19, 139.52, 152.78 (Lit.).

4,7-Bis(5′-bromo-2′-thienyl)-1,3,2-benzothiadiazole (BrTBTBr). TBT (0.11 g, 0.36 mmol) and NBS (0.16 g, 0.92 mmol) were dissolved into DMF (20 mL) and heated to 85° C. overnight. The mixture was then cooled to room temperature and quenched with a 10% KOH solution (10 mL). The formed red precipitate was filtered by suction and redissolved into methylene chloride. The solution was washed with water until neutral and dried over sodium sulfate. The solvent was then evaporated. The solid was recrystallized from hexanes and dried at vacuum to afford 0.10 g (60%) of an orange powder.

4,7-Bis[5′-(9″,9″-dihexyl-2″-fluorene-yl)-2′-thienylene]-1,3,2-benzothiadiazole (FTBTF). (9,9-dihexyl-2-fluorene-yl)-boronic acid (0.10 g, 0.26 mmol), BrTBTBr (0.036 g, 0.079 mmol), palladium tetrakis(triphenylphosphine) (0.0050 g, 0.0043 mmol) and ALIQUAT 336 (0.033 g, 0.0081 mmol) were set under nitrogen and then dissolved in dry toluene (10 mL). The mixture was heated to 80° C. and a 2 M solution of potassium carbonate (0.40 mL, 0.75 mmol) was added at once. The mixture was stirred at 110° C. overnight and then cooled to room temperature. The layers were separated and the aqueous one was extracted with methylene chloride. All organic layers were combined, washed with water until neutral and dried over sodium sulfate. The solvent was evaporated under reduced pressure and the red oil was purified via silica gel flash column chromatography with hexane/methylene chloride (0-5%) as eluent to afford 0.044 g (58%) of a purple powder. M.P. 147-148° C.; MS (FAB) m/z 964.8 (cal. m/z 964.49); ¹H NMR (300 MHz, CDCl₃) δ (ppm): 0.75 (t, J=6.6 Hz, 12H), 0.98-1.28 (m, 32H), 1.96-2.06 (m, 8H), 7.27-7.37 (m, 6H), 7.48 (d, J=4.2 Hz, 2H), 7.65 (s, 2H), 7.67-7.75 (m, 6H), 7.94 (s, 2H), 8.14 (d, J=4.2 Hz, 2H); ¹³C NMR (75 MHz, ¹H decoupled, CDCl₃) δ (ppm): 14.22, 22.80, 23.97, 29.92, 31.72, 40.66, 55.45, 99.51, 119.99, 120.33, 123.10, 124.14, 124.99, 125.52, 126.03, 127.06, 127.45, 128.85, 133.11, 138.52, 140.79, 141.37, 146.72, 151.17, 151.83, 152.87; Elemental Anal. Calc. for C₆₄H₇₂N₂S₃: C, 79.62; H, 7.52; N, 2.90, S, 9.96; found C, 78.84; H, 7.72; N, 2.88.

### Example 3

### The Synthesis of a Representative Emissive Host Compound: PF-TPA-OXD

In the example, the synthesis of a representative emissive host compound (PF-TPA-OXD), a blue light-emitting compound, useful in the device of the invention is described.

The synthesis and some properties of PF-TPA-OXD have been described by Jen et al. in “Highly Efficient Blue-Light-Emitting Diodes from Polyfluorene Containing Bipolar Pendant Groups,” Macromolecules 2003, 36, 6698-6703, and Jen et al. in “Bright Red-Emitting Electrophosphorescent Device Using Osmium Complex as a Triplet Emitter,” Appl. Phys. Lett. 2003, 83, 776-778, each reference is incorporated herein by reference in its entirety.

9,9-Bis(4-di(4-butylphenyl)aminophenyl)-2,7-dibromofluorene. To a mixture of 2,7-dibromofluorene (315 mg. 930 μmol) (prepared as described in Macromolecules 1999, 32, 3306) and 4,4′-dibutyltriphenylamine (1.0 g, 2.8 mmol) (prepared as described in Chem. Mater. 1997, 9, 3231) was added methanesulfonic acid (60 μL, 0.93 mmol). The reaction mixture was then heated at 140° C. under nitrogen for 12 h. The cooled mixture was diluted with dichloromethane and washed with aqueous sodium carbonate. The organic phase was dried over MgSO₄, and the solvent was evaporated. The crude product was purified by column chromatography, eluting with hexane/ethyl acetate (8:2), followed by recrystallization from acetone to afford 3 (0.50 g, 52%) as white crystals. ¹H NMR (300 MHz, CDCl₃): δ 0.91 (12H, t, J=7.4 Hz), 1.34 (8H, m), 1.56 (8H, m), 2.54 (8H, t, J=7.7 Hz), 6.84 (4H, d, J=8.7 Hz), 6.94 (4H, d, J=8.7 Hz), 6.97 (8H, d, J=8.4 Hz), 7.03 (8H, d, J=8.4 Hz), 7.44 (2H, dd, J=8.1, 1.5 Hz), 7.5 (2H, d, J=1.5 Hz), 7.54 (2H, d, J=8.1 Hz). ¹³C NMR (75 MHz, CDCl₃): δ 153.7, 147.1, 145.2, 137.9, 137.7, 136.6, 130.7, 129.4, 129.1, 128.5, 124.8, 121.7, 121.6, 121.4, 64.6, 35.0, 33.6, 22.4, 14.0. Anal. Calcd for C₆₅H₆₆Br₂N₂: C, 75.43; H, 6.43; N, 2.71. Found: C, 75.41; H, 6.56; N, 2.25.

PF-TPA-OXD. To a solution of 9,9-bis(4-di(4-butylphenyl)aminophenyl)-2,7-dibromofluorene (161 mg, 156 μmol), oxadiazole monomer (137 mg, 156 μmol) (prepared as described in Chem. Mater. 2003, 15, 269), and 2,7-bis-(4,4,5,5-tetramethyl-1,3,2-dioxaborolan-2-yl)-9,9-dioctylfluorene (200.0 mg, 312 μmol) (prepared as described in Macromolecules 1997, 30, 7686) in toluene (4.0 mL) were added aqueous potassium carbonate (2.0 M, 4.0 mL) and ALIQUATE 336 (20 mg). The above solution was degassed, and tetrakis(triphenylphosphine)palladium (10 mg, 5.5 mol %) was added in one portion under a nitrogen atmosphere. The solution was refluxed under nitrogen for 3 days. The end groups were capped by refluxing for 12 h each with phenylboronic acid (40 mg, 0.33 mmol) and bromobenzene (52 mg, 0.33 mmol). After this period, the mixture was cooled and poured into a mixture of methanol and water (150 mL, 7:3 v/v). The crude polymer was filtered, washed with excess methanol, and dried. The polymer was dissolved in CHCl₃ (2.0 mL), filtered, and precipitated into methanol (150 mL). The precipitate was collected, washed with acetone for 24 h using a Soxhlet apparatus, and dried under vacuum to give PF-TPA-OXD (270 mg, 73%). ¹H NMR (300 MHz, CDCl₃): δ 0.69-0.75(20H, m), 0.89 (12H, t, J=7.5 Hz), 1.02-1.19 (40H, m), 1.24-1.40 (26H, m), 1.57 (8H, m), 2.04 (8H, m), 2.54 (8H, m), 6.89-7.16 (24H, m), 7.51-7.84 (30H, m), 7.93-8.11 (10H, m). ¹³C NMR (75 MHz, CDCl₃): δ 164.8, 164.1, 155.4, 152.9, 151.9, 151.8, 150.9, 149.3, 146.8, 145.4, 141.9, 141.1, 140.4, 140.3, 139.8, 139.1, 138.9, 138.6, 137.6, 129.1, 129.0, 128.9, 127.7, 127.4, 127.3, 126.8, 126.3, 126.1, 124.7, 123.0, 121.9, 121.4, 121.1, 120.9, 120.4, 120.1, 65.9, 64.8, 55.4, 40.4, 35.2, 35.1, 33.7, 31.8, 31.2, 30.0, 29.2, 23.9, 22.6, 22.4, 14.1, 14.0. Anal. Calcd for C₁₇₂H₁₈₆N₆O₂: C, 87.19; H, 7.91; N, 3.55. Found: C, 86.27; H, 7.73; N, 3.11.

### Example 4

### The Fabrication of a Representative White Light-Emitting Device

In the example, the fabrication of a representative white light-emitting device of the invention is described. The representative device is a double-layer light-emitting device: ITO/PEDOT/PF-TPA-OXD:FFBFF:FTBTF/Ca/Ag. A schematic illustration of a representative double-layer device is shown in FIG. 5B.

The representative devices were fabricated on indium tin oxide (ITO)-coated glass substrate that was pre-cleaned and treated with oxygen plasma before use. A layer of 20 nm-thick poly(ethylenedioxythiophene): polystyrene sulfonate (PEDOT, Bayer Co.) was deposited first by spin-coating from its aqueous solution (1.3 wt. %) and annealed at 160° C. for 10 min under nitrogen. An emissive layer with green- and red-emitting dyes (FFBFF and FTBTF) dispersed in PF-TPA-OXD was then spin-coated at 2000 rpm from its toluene solution (about 15 mg/mL) on top of the PEDOT layer. The emissive layer included about 0.18 weight percent FFBFF and about 0.11 weight percent FTBTF. The typical thickness of the emissive layer was about 50 nm. Afterward, a layer of calcium (Ca) (about 30 nm) was vacuum deposited (at about 1×10⁻⁶ torr) on top of the emissive layer as cathode and finally a layer of silver (Ag) (about 120 nm) was deposited as the protecting layer.

While the preferred embodiment of the invention has been illustrated and described, it will be appreciated that various changes can be made therein without departing from the spirit and scope of the invention.

The embodiments of the invention in which an exclusive property or privilege is claimed are defined as follows:

1. A light-emitting device, comprising an emissive layer intermediate first and second electrodes, the emissive layer comprising a first compound having emission in the range from about 520 nm to about 600 nm, a second compound having an emission in the range from about 620 to about 720 nm, in an emissive host material having emission in the range from about 420 to about 480 mm.

2. The device of claim 1 further comprising an electron transporting layer intermediate the emissive layer and the second electrode.

3. The device of claim 2 further comprising a hole transporting layer intermediate the first electrode and the emissive layer.

4. The device of claim 3 further comprising an electron injection layer intermediate the emissive layer and the second electrode.

5. The device of claim 4 further comprising an electron transporting layer intermediate the emissive layer and the electron injection layer.

6. The device of claim 1, wherein the first compound is FFBFF or a derivative thereof.

7. The device of claim 1, wherein the first compound is present in the emissive layer in an amount from about 0.10 to about 0.30 percent by weight based on the total weight of the emissive layer.

8. The device of claim 1, wherein the second compound is FTBTF or a derivative thereof.

9. The device of claim 1, wherein the second compound is present in the emissive layer in an amount from about 0.05 to about 0.15 percent by weight based on the total weight of the emissive layer.

10. The device of claim 1, wherein the host material is PF-TPA-OXD or derivative thereof.

11. The device of claim 1, wherein the first compound comprises one or more fluorenyl moieties.

12. The device of claim 1, wherein the second compound comprises one or more fluorenyl moieties.

13. The device of claim 1, wherein the host material comprises one or more fluorenyl moieties.

14. The device of claim 1, wherein the first compound, second compound, and host material each comprise one or more fluorenyl moieties.

15. The device of claim 1, wherein the first compound comprises one or more 9,9-dialkyl fluorenyl moieties.

16. The device of claim 1, wherein the second compound comprises one or more 9,9-dialkyl fluorenyl moieties.

17. The device of claim 1, wherein the host material comprises one or more 9,9-dialkyl fluorenyl moieties.

18. The device of claim 1, wherein the first compound, the second compound, and the host material each have an absorbance spectrum and an emission spectrum, wherein the emission spectrum of the host material sufficiently overlaps the absorbance spectrum of the first compound to effect energy transfer from the host material to the first compound, and wherein the emission spectrum of the first compound sufficiently overlaps the absorbance spectrum of the second compound to effect energy transfer from the first compound to the second compound.

19. The device of claim 1, wherein the light produced by the device is substantially pure white light.

20. The device of claim 1, wherein the light produced by the device has CIE chromaticity coordinates: x=0.30-0.36, y=0.34-0.37 at a bias of 6 V.

21. The device of claim 1, wherein the light produced by the device has CIE chromaticity coordinates: x=0.32-0.34, y=0.34-0.38 at a bias of 12 V.
